(19) United States
(12) Patent Application Publication
(10) Pub. No.: US 2016/0126160 A1
(43) Pub. Date: May 5, 2016

(54) SYSTEM FOR COOLING DUAL SIDES OF POWER SEMICONDUCTOR DEVICE

(71) Applicant: HYUNDAI MOBIS CO., LTD., Seoul (KR)

(72) Inventor: Eui-Soo JEONG, Yongin-si (KR)

(21) Appl. No.: 14/702,381

(22) Filed: May 1, 2015

(30) Foreign Application Priority Data
Nov. 3, 2014 (KR) 10-2014-0151100

(51) Int. Cl. H01L 23/473; H01L 23/492; H05K 7/20

(52) U.S. Cl. CPC H01L 23/473; H05K 7/20272; H05K 7/20927; H01L 23/492

(57) ABSTRACT

A system for cooling dual sides of power semiconductor devices includes two (2) cooling water flow passages, each of which being bent in the “ [symbol] ” or “S” shape, to allow a plurality of power semiconductor devices to be inserted in the cooling water flow passage and to allow each power semiconductor device to be connected to an external device.

### CROSS-REFERENCE(S) TO RELATED APPLICATIONS

This application claims priority to Korean Patent Application No. 10-2014-0151100 filed on Nov. 3, 2014, which is incorporated herein by reference in its entirety.

### BACKGROUND

The present disclosure relates to a system for cooling dual sides of a power semiconductor device.

Generally, power semiconductor devices are used in a vehicle. When operating, the power semiconductor devices generate heat. To protect the power semiconductor devices from excessive heat, the vehicle includes a cooling apparatus.

### SUMMARY

An aspect of the present invention provides a system for cooling dual sides of a power semiconductor device, in which a plurality of power semiconductor devices are inserted in two (2) cooling water flow passages, each of which being bent into the “ [symbol] ” or “S” shape, and a cooling unit including the cooling water flow passages in which the power semiconductor devices are inserted is secured to a fixing plate to enable the power semiconductor devices to be connected to an external device, whereby a plurality of power semiconductor devices can be cooled by a small number of cooling water flow passages so that a cooling efficiency is excellent, an air-tightness of the cooling water passage can be guaranteed and the power semiconductor device is easily mounted to the cooling unit.

Another aspect of the invention provides a system for cooling power semiconductor devices in a vehicle, which may comprise; a flat conduit for flowing a coolant therethrough; the flat conduit comprising a first linear portion, a second linear portion and a third linear portion connected serially and arranged such that the second linear portion is interposed between the first and third linear portions; a first power semiconductor device interposed between the first and second linear portions and comprising two surfaces contacting the first and second linear portions, respectively; and a second power semiconductor device interposed between the second and third linear portions and comprising two surfaces contacting the second and third linear portions, respectively.

A system for cooling dual sides of a power semiconductor device in accordance with embodiments of the present invention may include at least one power semiconductor device; a cooling unit provided for cooling the power semiconductor device and having a bending shape to pressurize an upper surface and a lower surface of the power semiconductor device; and a connecting unit for connecting the power semiconductor device to an external device.

At this time, the cooling unit may include a cooling water flow passage in which the power semiconductor device is inserted, the cooling water flowing passage having a bending shape to pressurize an upper surface and a lower surface of the power semiconductor device; a first distributor for supplying cooling water to the cooling water flow passage; a second distributor to which cooling water in the cooling water flow passage is discharged; a cooling water inlet through which cooling water is supplied to the first distributor; and a cooling water outlet through which cooling water is discharged from the second distributor.

Here, the cooling water flow passage may be bent into the “ [symbol] ” or “C” shape or into the “ [symbol] ” or “S” shape, or the cooling water flow passage may be bent a couple of times to form a multiple stack structure In addition, a plurality of cooling water flow passages may be mounted between the first distributor and the second distributor, and a plurality of power semiconductor devices may be inserted in the cooling water flow passage.

In addition, the connecting unit may include a connecting terminal for connecting the power semiconductor device to the external device; a fixing plate to which the connecting terminal is mounted and the cooling unit is secured; and an upper fixing plate coupled to the fixing plate to pressurize an upper surface and a lower surface of the cooling unit for securing the cooling unit.

One embodiment of a method for manufacturing a cooling unit constituting of a system for cooling dual sides of a power semiconductor device according to the present invention may include a flow passage fabricating step of fabricating a cooling water flow passage, a first distributor, a second distributor, a cooling water inlet and a cooling water outlet; a flow passage bending step of bending the cooling water flow passage; a flow passage connecting step of connecting the bent cooling water flow passage to the first and second distributors; an inlet/outlet connecting step of welding the cooling water inlet to the first distributor and coupling the cooling water outlet to the second distributor; and an air-tightness inspecting step of inspecting the air-tightness of the coupled cooling unit.

In the flow passage bending step, at this time, the cooling water passage may be bent into the “ [symbol] ” or “S” shape.

In addition, in the flow passage connecting step, a plurality of bent cooling water passages may be coupled to the first and second distributors.

Furthermore, in the flow passage connecting step or in the inlet/outlet connecting step, the coupling may be achieved by means of a brazing process.

### BRIEF DESCRIPTION OF THE DRAWINGS

FIG. 1 is a front view illustrating one example of an apparatus for cooling a power semiconductor device;

FIG. 2 is a perspective view illustrating one example of an apparatus for cooling a power semiconductor device;

FIG. 3 is a perspective view illustrating another example of an apparatus for cooling a power semiconductor device;

FIG. 4 is a perspective view illustrating a system for cooling dual sides of a power semiconductor device in accordance with the present invention;

FIG. 5 is a front view illustrating a system for cooling dual sides of a power semiconductor device in accordance with the present invention;

FIG. 6 is an exploded perspective view illustrating a system for cooling dual sides of a power semiconductor device in accordance with the present invention;

FIG. 7 is a perspective view illustrating a power semiconductor device of a system for cooling dual sides of a power semiconductor device in accordance with the present invention;

FIG. 8 is a perspective view illustrating a cooling unit constituting a system for cooling dual sides of a power semiconductor device in accordance with the present invention; and

FIG. 9 is a flow chart for illustrating a method for manufacturing a cooling unit of a system for cooling dual sides of a power semiconductor device in accordance with the present invention.

### DESCRIPTION OF EMBODIMENTS

Embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

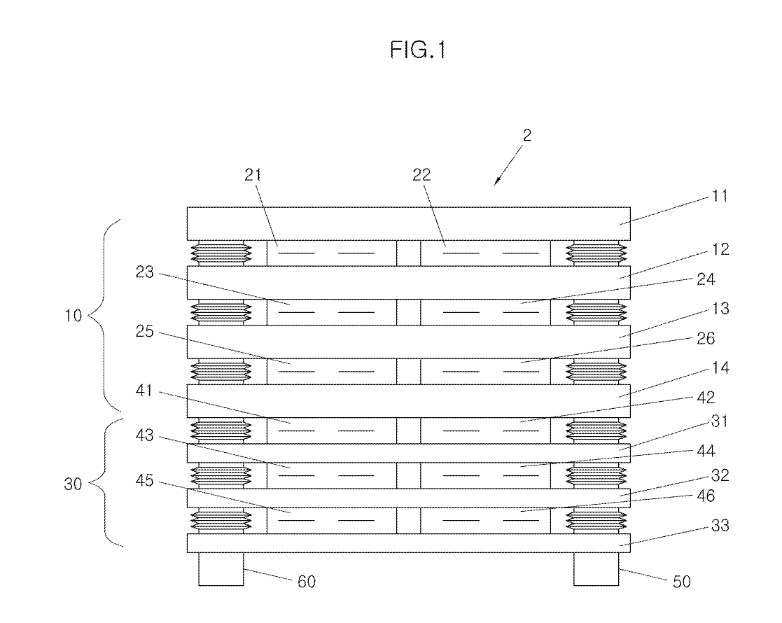

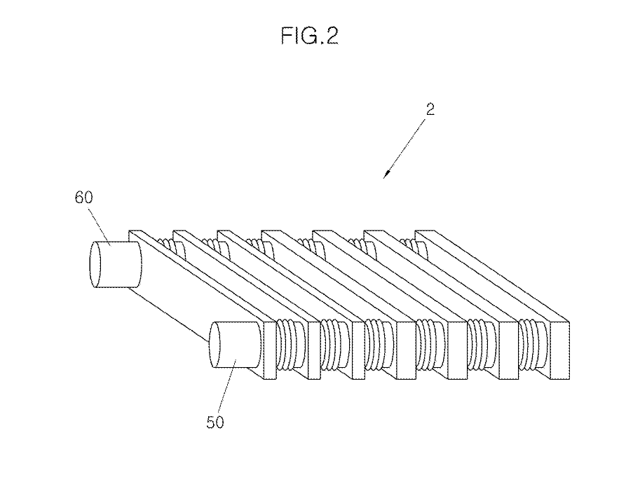

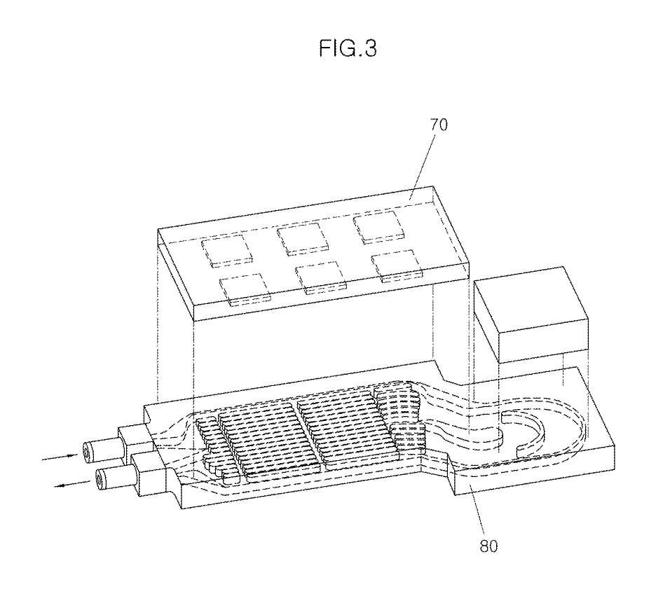

FIG. 1 is a front view illustrating one example of an apparatus for cooling a power semiconductor device, FIG. 2 is a perspective view illustrating one example of an apparatus for cooling a power semiconductor device and FIG. 3 is a perspective view illustrating another example of an apparatus for cooling a power semiconductor device.

Referring to FIG. 1 and FIG. 2, an apparatus 2 for cooling a power semiconductor device includes a first cooler 10, a second cooler 30 and power semiconductor devices 20 and 40. In more detail, in the first cooler 10, a plurality of cooling water flow passages 11, 12, 13 and 14 are overlapped in the longitudinal direction, and the power semiconductor devices 21, 22, 23, 24, 25 and 26 with high calorific value are inserted between the cooling water flow passages. The second cooler 30 consists of a plurality of cooling water flow passages 31, 32 and 33 which are overlapped in the longitudinal direction below the first cooler 10 and the power semiconductor devices 41, 42, 43, 44, 45, 46 with low calorific value are inserted between the cooling water flow passages.

However, the above apparatus 2 for cooling a power semiconductor device is disadvantageous in that since the plurality of cooling water flow passages 10 and 20 and the cooling water inlet/outlet pipes 50 and 60 should be brazed to each other, the structure is complicated and it is difficult to guarantee air-tightness of the cooling water flow passage.

In addition, since there are a plurality of cooling water passages 33, 32, 31, 14, 13, 12 and 11 diverged from the cooling water inlet pipe 50, cooling water does not flow smoothly. Furthermore, since the cooling apparatus 2 has the structure in which the power semiconductor devices must be inserted from top to bottom, this cooling apparatus is unsuitable for mounting a power semiconductor device for a motor vehicle employing a screw coupling manner.

Referring to FIG. 3, an apparatus 3 for cooling a power semiconductor device has a structure in which an additional cooling device 80 is installed below a power semiconductor device mounting part 70. However, in the above apparatus 3 for cooling a power semiconductor device, a cooling efficiency is lowered due to the additional cooling device installed below the power semiconductor device mounting part and a manufacturing cost is increased by the power semiconductor device mounting part 70 and the cooling device 80 which are independently fabricated.

Therefore, an apparatus for cooling a power semiconductor device, which has a cooling water flow passage structure by which an air-tightness of a cooling water flow passage can be secured and a cooling efficiency can be enhanced, and can improve a performance for mounting a power semiconductor device, has been required.

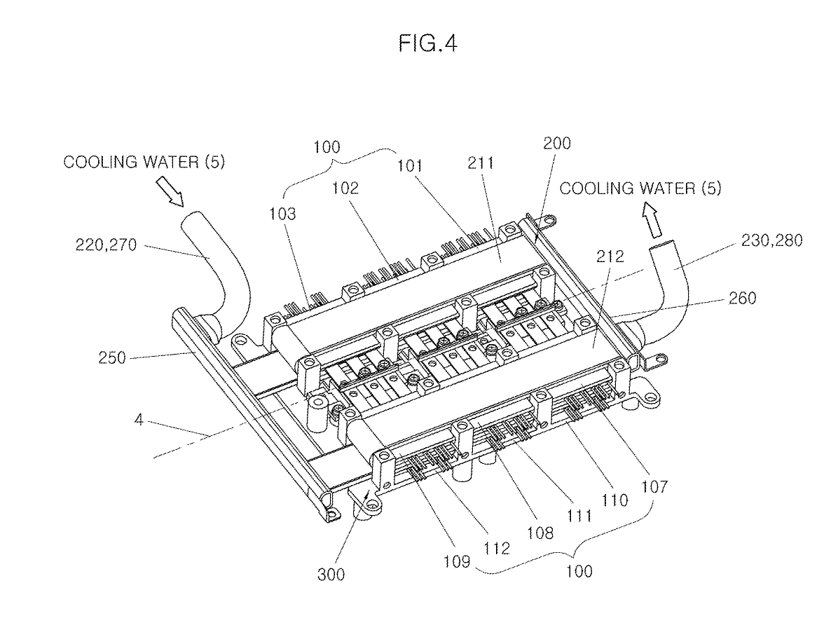

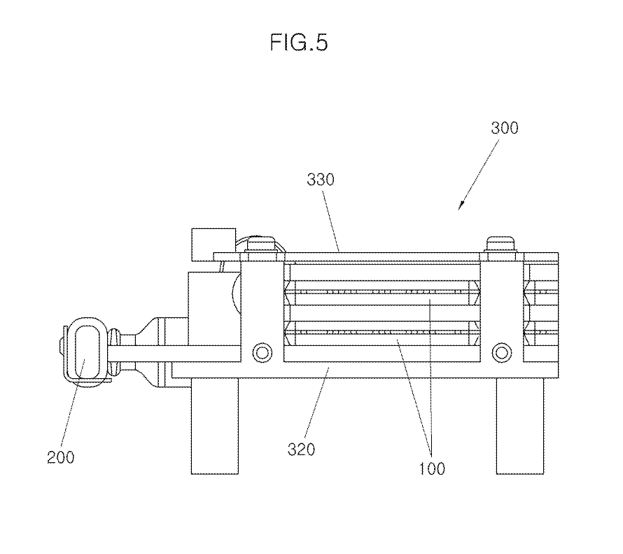

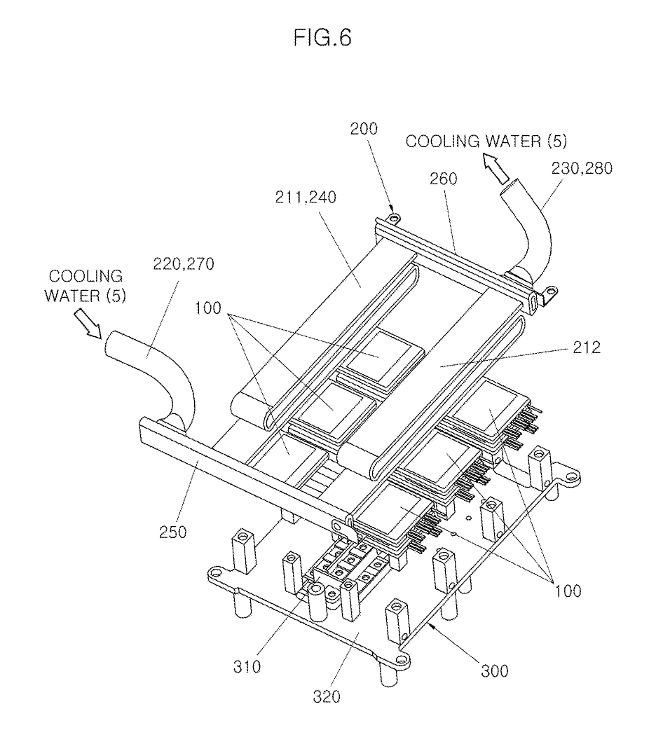

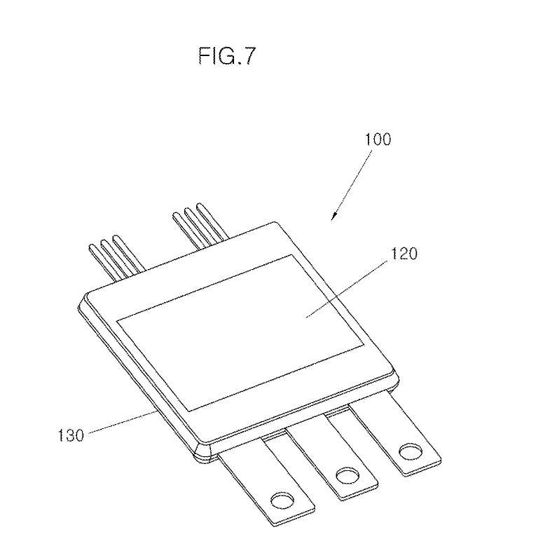

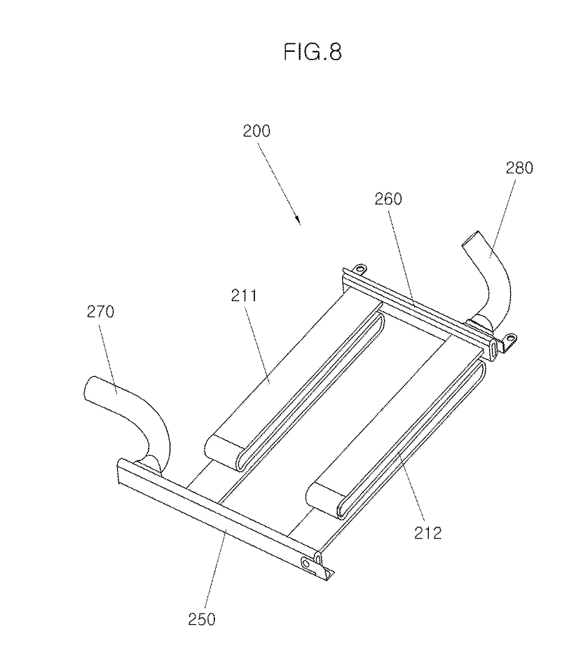

FIG. 4 is a perspective view illustrating a system for cooling dual sides of a power semiconductor device in accordance with the present invention, FIG. 5 is a front view illustrating a system for cooling dual sides of a power semiconductor device in accordance with the present invention, FIG. 6 is an exploded perspective view illustrating a system for cooling dual sides of a power semiconductor device in accordance with the present invention, FIG. 7 is a perspective view illustrating a power semiconductor device of a system for cooling dual sides of a power semiconductor device in accordance with the present invention, and FIG. 8 is a perspective view illustrating a cooling unit constituting a system for cooling dual sides of a power semiconductor device in accordance with the present invention.

Referring to FIG. 4 to FIG. 8, a system for cooling dual sides of a power semiconductor device in accordance with one embodiment of the present invention may include a power semiconductor device 100, a cooling unit 200 and a connecting unit 300.

The power semiconductor device 100 is inserted into the cooling unit 200 and is coupled to the connecting unit 300 so that the power semiconductor device is electrically connected to an external device. Here, as the power semiconductor device 100 inserted into the cooling unit 200, the total of 12 (twelve) power semiconductor devices including three (3) power semiconductor devices 101, 102 and 103 for a high voltage DC-DC converter, three (3) power semiconductor devices 104, 105 and 106 for a first motor MG1 and the other six (6) power semiconductor devices 107, 108, 109, 110, 111 and 112 may be utilized. Referring to FIG. 8 illustrating the cooling unit 200 including two cooling water flow passages 211 and 212 and first and second distributors 250 and 260, in the cooling unit 200 including two (2) “ [symbol] ” or “S” shaped cooling water flow passages 211 and 210, three (3) power semiconductor devices may be inserted into an upper space, in which no cooling water flow passage is existed, of one “ [symbol] ” or “S” shaped cooling water flow passage 211, and three (3) power semiconductor devices may be inserted into a lower space, in which no cooling water flow passage is existed, of one “ [symbol] ” or “S” shaped cooling water flow passage 211. Consequently, the total of 12 (twelve) power semiconductor devices may be mounted to the cooling unit 200 including two [symbol] ” shaped cooling water flow passages 211 and 212. In order to electrically connect the power semiconductor devices to the connecting unit 300, at this time, a plurality of power semiconductor devices 101, 102, 103, 104, 105, 106, 107, 108, 109, 110, 111 and 112 may be inserted into the cooling unit 200 so that the terminals of the power semiconductor devices, each of which being provided for connecting each power semiconductor device to an external device, are directed toward a central axis 4 between two cooling water flow passages 211 and 212

The cooling unit 200 has a bending shape to pressurize an upper surface 120 and a lower surface 130 of the power semiconductor device and cools the power semiconductor device 100. In other words, the cooling unit 200 is provided for cooling the power semiconductor device 100, which is inserted in a space formed in the bending shaped cooling unit, with cooling water 5 flowing in the cooling unit. In more detail, the cooling unit according to the first embodiment may include a cooling water flow passage 210, a cooling water inlet 220 and a cooling water outlet 230. In addition, the cooling unit according to the second embodiment may include a cooling water flow passage 240, a first distributor 250, a second distributor 260, a cooling water inlet 270 and a cooling water outlet 280.

Hereinafter, structure elements of the cooling unit according to the second embodiment of the present invention are illustrated. It may be interpreted that the structural elements 210, 220 and 230 of the cooling unit of the first embodiment, which are the same as those of the cooling unit of the second embodiment, perform the functions which are the same as those performed by the structural elements 240, 270 and 280 of the cooling unit of the second embodiment.

The cooling water flow passage 240 has a bending shape to pressurize the upper surface 120 and the lower surface 130 of the power semiconductor device and the power semiconductor device 100 is inserted in the cooling water flow passage. In other words, the cooling water flow passage 240 is bent into the “ [symbol] ” or “C” shape or the “ [symbol] ” or “S” shape, and the power semiconductor device 100 can be inserted in a space formed between two adjacent portions of the bent cooling water flow passage. In addition, the cooling water flow passage 240 may have a multiple stack structure by bending it a couple of times. For example, two or more cooling water flow passages, each of which having the “ [symbol] ” or “S” shape, can overlap each other to form the cooling water flow passage having the multiple stack structure, more power semiconductor devices can be inserted in the cooling water flow passage having the multiple stack structure.

Furthermore, a plurality of cooling water flow passages 240 can be mounted between the first distributor 250 and the second distributor 260. As shown in FIG. 8, in other words, two (2) cooling water flow passages 211 and 212 having the “ [symbol] ” or “S” shape may be mounted between the first distributor 250 and the second distributor 260. However, the number and the shape of the cooling water flow passage mounted between the first distributor 250 and the second distributor 260 are not limited. Here, a plurality of power semiconductor devices 101, 102, 103, 104, 105, 106, 107, 108, 109, 110, 111 and 112 may be inserted in the cooling water flow passage. At this time, according to the shape of the cooling water flow passage 210, the direction in which the power semiconductor device 100 is inserted in the cooling water flow passage 210 may be varied. For example, where the cooling water flow passage 211 or 212 has the “ [symbol] ” or “S” shape, the power semiconductor device 100 may be inserted in one space, which is formed above a central part of the “ [symbol] ” or “S” shaped cooling water flow passage 211 or 212, from the right to the left, and the power semiconductor device 100 may be inserted in the other space, which is formed below a central part of the “ [symbol] ” or “S” shaped cooling water flow passage 211 or 212, from the left to the right.

The first distributor 250 supplies the cooling water to the cooling water flow passages 211 and 212. In other words, the first distributor 250 act as a passage through which cooling water discharged from the cooling water inlet 270 is supplied to the cooling water flow passages 211 and 212. In the first embodiment in which the first distributor 250 is not provided, the cooling water inlet 270 can function as the first distributor 250.

Cooling water is discharged from the cooling water flow passages 211 and 212 to the second distributor 260. In other words, the second distributor 260 acts as a passage to which cooling water discharged from the cooling water flow passages 211 and 212 flows, and cooling water discharged from the second distributor flows to the cooling water outlet 280. In the first embodiment in which the second distributor 260 is not provided, the cooling water outlet 280 can function as the second distributor 260.

The cooling water inlet 270 supplies cooling water to the first distributor 250. Here, the cooling water inlet 270 may be mounted to the first distributor 250, and a shape and a direction of the cooling water inlet 270 may be varied according to a flow rate of the cooling water and a place of source of cooling water.

Cooling water is discharged from the second distributor to the cooling water outlet 280. Here, the cooling water outlet 280 may be mounted to the second distributor 260, and a shape and a direction of the cooling water outlet 280 may be varied according to a flow rate of the cooling water 5 and a location of a cooling water supplying source.

The connecting unit 300 connects the power semiconductor device to the external device. In more detail, the connecting unit may include a connecting terminal 310, a fixing plate 320 and an upper fixing plate 330.

The power semiconductor device 100 is electrically connected to the external device via the connecting terminal 310. In other words, the connecting terminal 310 can be coupled to a terminal of the power semiconductor device 100, which is employed for an external connection, via a bolt to electrically connect the power semiconductor device to an external load or a battery.

The connecting terminal 310 is mounted to the fixing plate 320, and the fixing plate secures the cooling unit 200. In other words, the connecting terminal 310 to which the terminal of the power semiconductor device 100, which is employed for an external connection, is coupled is mounted to the fixing plate 320, and the fixing plate can secure the cooling unit 200 into which the power semiconductor device 100 is inserted.

The upper fixing plate 330 is coupled to the fixing plate 320 to pressurize the upper surface and the lower surface of the cooling unit and to then secure the cooling unit 200. As shown in FIG. 5, in other words, the upper fixing plate 330 can pressurize the cooling unit 200 in which the power semiconductor devices 100 are inserted, in the vertical direction and secure the cooling unit.

Hereinafter, one embodiment of a method for manufacturing the cooling unit of the system for cooling dual sides of the power semiconductor device in accordance with the present invention is described in detail with reference to the accompanying drawings.

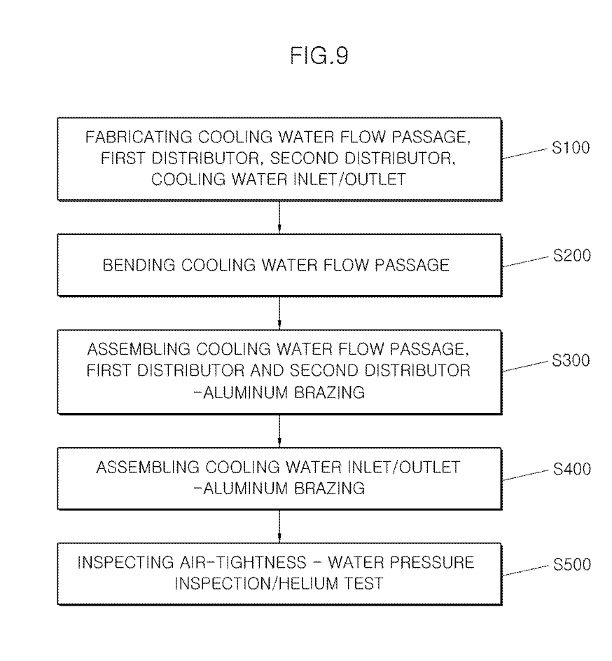

FIG. 9 is a flow chart for illustrating a method for manufacturing the cooling unit of the system for cooling dual sides of the power semiconductor device in accordance with the present invention.

Referring to FIG. 9, one embodiment of a method for manufacturing the cooling unit of the system for cooling dual sides of the power semiconductor device in accordance with the present invention may comprise a flow passage fabricating step S100, a flow passage bending step S200, a flow passage connecting step S300, an inlet/outlet connecting step S400 and an air-tightness inspecting step S500.

In the flow passage fabricating step S100, the cooling water flow passage 210, the first distributor 250 and the second distributor 260 are fabricated. In addition, the cooling water inlet 270 and the cooling water outlet 280 may be further fabricated in the flow passage fabricating step S100.

In the flow passage bending step S200, the cooling water flow passage 210 is bent. At this time, the cooling water flow passage 210 may be bent into the “ [symbol] ” or “C” shape or the “ [symbol] ” or “S” shape or can be bent a couple of times to allow the cooling water flow passage to have a multiple stack structure in the flow passage bending step S200.

In the flow passage connecting step S300, the bent cooling water flow passage 210 is coupled to the first and second distributors 250 and 260. At this time, in the flow passage connecting step S300, a plurality of bent cooling water flow passages 210 may be coupled to the first and second distributors 250 and 260. Here, the above coupling may be achieved by means of a brazing process.

In the inlet/outlet connecting step S400, the cooling water inlet 270 is welded to the first distributor 250 and the cooling water outlet 280 is coupled to the second distributor 260. At this time, the above coupling may be achieved by a brazing process.

In the air-tightness inspecting step S500, the air-tightness of the cooling unit 200 completed through the above connecting steps is inspected.

According to the system for cooling dual sides of the power semiconductor device in accordance with the present invention, since the plurality of power semiconductor devices are cooled by a small number of cooling water flow passages, an excellent cooling efficiency is obtained, the air-tightness of the cooling water passage can be guaranteed, and the power semiconductor devices are easily mounted to the cooling unit.

While the present invention has been described with respect to the specific embodiments, it will be apparent to those skilled in the art that various changes and modifications may be made without departing from the spirit and scope of the invention as defined in the following claims.

What is claimed is:

1. A system for cooling dual sides of a power semiconductor device, comprising;
a cooling unit provided for cooling the power semiconductor device, the cooling unit having a bending shape to pressurize an upper surface and a lower surface of the power semiconductor device; and
a connecting unit for connecting the power semiconductor device to an external device.

2. The system for cooling dual sides of the power semiconductor device of claim 1, wherein the cooling unit comprises;
a cooling water flow passage in which the power semiconductor device is inserted, the cooling water flowing passage having a bending shape to pressurize an upper surface and a lower surface of the power semiconductor device;
a cooling water inlet for supplying cooling water to the cooling water flow passage; and
a cooling water outlet for discharging cooling water from the cooling water flow passage.

3. The system for cooling dual sides of the power semiconductor device of claim 1, wherein the cooling unit comprises
a cooling water flow passage in which the power semiconductor device is inserted, the cooling water flowing passage having a bending shape to pressurize an upper surface and a lower surface of the power semiconductor device;
a first distributor for supplying cooling water to the cooling water flow passage;
a second distributor to which cooling water in the cooling water flow passage is discharged;
a cooling water inlet through which cooling water is supplied to the first distributor; and
a cooling water outlet through which cooling water is discharged from the second distributor.

4. The system for cooling dual sides of the power semiconductor device of claim 1, wherein the connecting unit comprises
a connecting terminal for connecting the power semiconductor device to the external device; and
a fixing plate to which the connecting terminal is mounted and the cooling unit is secured.

5. The system for cooling dual sides of the power semiconductor device of claim 2, wherein the cooling water flow passage is bent to be C-shaped.

6. The system for cooling dual sides of the power semiconductor device of claim 2, wherein the cooling water flow passage is bent to be S-shaped.

7. The system for cooling dual sides of the power semiconductor device of claim 2, wherein the cooling water flow passage is bent a couple of times to form a multiple stack structure.

8. The system for cooling dual sides of the power semiconductor device of claim 2, wherein a plurality of power semiconductor devices are inserted in the cooling water flow passage.

9. The system for cooling dual sides of the power semiconductor device of claim 3, wherein the cooling water flow passage is bent to be C-shaped.

10. The system for cooling dual sides of the power semiconductor device of claim 3, wherein the cooling water flow passage is bent to be S-shaped.

11. The system for cooling dual sides of the power semiconductor device of claim 3, wherein the cooling water flow passage is bent a couple of times to form a multiple stack structure.

12. The system for cooling dual sides of the power semiconductor device of claim 3, wherein the plurality of cooling water flow passages are disposed between the first distributor and the second distributor.

13. The system for cooling dual sides of the power semiconductor device of claim 3, wherein a plurality of power semiconductor devices are inserted in the cooling water flow passage.

14. The system for cooling dual sides of the power semiconductor device of claim 4, wherein the connecting unit further comprises an upper fixing plate coupled to the fixing plate to pressurize an upper surface and a lower surface of the cooling unit for securing the cooling unit.

15. A method for manufacturing a cooling unit constituting of a system for cooling dual sides of a power semiconductor device, comprising;
a flow passage fabricating step of fabricating a cooling water flow passage, a first distributor, a second distributor, a cooling water inlet and a cooling water outlet;
a flow passage bending step of bending the cooling water flow passage;
a flow passage connecting step of connecting the bent cooling water flow passage to the first and second distributors;
an inlet/outlet connecting step of welding the cooling water inlet to the first distributor and coupling the cooling water outlet to the second distributor; and
an air-tightness inspecting step of inspecting the air-tightness of the coupled cooling unit.

16. The method for manufacturing a cooling unit constituting of a system for cooling dual sides of a power semiconductor device of claim 15, wherein, in the flow passage bending step, the cooling water passage is bent to be S-shaped.

17. The method for manufacturing a cooling unit constituting of a system for cooling dual sides of a power semiconductor device of claim 15, wherein, in the flow passage connecting step, a plurality of bent cooling water passages are coupled to the first and second distributors.

18. The method for manufacturing a cooling unit constituting of a system for cooling dual sides of a power semiconductor device of claim 15, wherein, in the flow passage connecting step or in the inlet/outlet connecting step, the coupling is achieved by means of a brazing process.
